(19) United States
(12) Patent Application Publication
(10) Pub. No.: US 2005/0171835 A1
(43) Pub. Date: Aug. 4, 2005

(54) System for monitoring economic trends in fleet management network

(76) Inventors: David A. Mook, Solon, OH (US); Donald A. George, Cleveland, OH (US)

Correspondence Address: Mark A. Litman & Associates, P.A.;Suite 205, York Busines Center, 3209 West 76th St., Edina, MN, 55435, US

(21) Appl. No.: 11/035,829

(22) Filed: Jan. 14, 2005

Related U.S. Application Data
(60) Provisional application No. 60/538,192, filed on Jan. 20, 2004.

(51) Int. Cl. H03D 3/22

(52) U.S. Cl. 705/11

(57) ABSTRACT

A computer-based system monitors economic performance within a fleet of carriers comprises components of a communication network that provides information regarding at least individual carriers within the fleet of carriers to a processor. The processor contains a software program that: tabulates at least some of the information to provide a resource of economic performance within the fleet of carriers; enables graphic representation of at least some measures of the economic performance; and enables viewing of metrics including at least two parameters for evaluating the economic performance of a specific carrier. The processor may automatically evaluate individual carrier metrics and automatically alert a designated party of failure to operate within acceptable operating tolerances. The processor may also provide signals to a display unit that receives information from the processor that automatically displays reports that are key performance indicators. It is emphasized that this abstract is provided to comply with the rules requiring an abstract that will allow a searcher or other reader to quickly ascertain the subject matter of the application. It is submitted with the understanding that it will not be used to interpret or limit the scope or meaning of the claims.

### BACKGROUND OF THE INVENTION

1. Field of the Invention

The present invention relates to the field of fleet management, particularly carrier fleet management, and most particularly to the management and analysis of profitability characteristics of existing fleet contracts, carriers and traffic.

2. Background of the Art

Transportation systems are the backbone of modern economies. Efficient transportation is highly valuable, lowering expenses, reducing pollution, and utilizing expensive transportation assets so that they are more often moving goods and services and less often traveling empty or inefficiently. Although computers have been employed in transportation systems, logistical systems and planning have not delivered the improvements that Enterprise Resource Planning (ERP) and Just In Time (JIT) systems have delivered to other industries. Numerous methods and devices have been developed to move goods and people efficiently from point to point. These methods include systems that enable vehicles involved in transportation to be tracked and monitored. For example, U.S. Pat. No. 5,428,546 (Shah, et al.) relates to a system for tracking vehicle locations and displaying the locations via visual monitoring devices. Shah and similar systems enable a remote user to track vehicles in real-time but are largely focused on the problem of theft recovery. There are also systems for managing traffic information. For example, U.S. Pat. No. 5,465,289 (Kennedy) relates to a method for providing vehicle traffic information using cellular telephone technology. U.S. Pat. No. 5,299,132 (Wortham) facilitates locating vehicles through cellular telephone technology. U.S. Pat. No. 5,317,323 (Kennedy et al.) relates to a vehicle locating system utilizing Global Positioning Satellite System (GPS) and cellular telephones. U.S. Pat. No. 5,396,429 (Hanchett) employs roadway sensors and cameras for monitoring traffic flow. Other systems facilitate monitoring vehicle security with respect to theft and tampering, as described for example in U.S. Pat. No. 5,218,367 (Sheffer et al.). U.S. Pat. No. 6,304,816 (Berstis) relates to a method and apparatus for automatic data collection from vehicles that facilitates inferring current traffic conditions.

The management of a large fleet of remote assets, particularly when the fleet of assets comprises a fleet of mobile assets, such as a fleet of trucks, ships or railway locomotives, is a challenging logistical effort. There is continuing pressure for the owners and/or lessors of such assets to improve the efficiency of operations of the assets to remain competitive in the market place. For example, railroads must manage their fleets of locomotives to maximize the on-train time in order to remain competitive with alternative modes of transportation. The assignee of the present invention is a supplier of locomotive engines and has developed numerous design features and services to maximize the efficiency of operation of its locomotives. The inventor provides integrated maintenance services to the owners and/or lessors of automotive assets. Such services may include managing fleet-related data among a plurality of maintenance service centers that supply necessary parts and labor. The coordination of the servicing of a large fleet of mobile assets and the communication with the various parties involved in such efforts are monumental tasks.

U.S. Pat. No. 5,845,272 relates to a system and method for diagnosing failures in a locomotive. While such a system and method has proven beneficial, further improvements in fleet management are desired.

U.S. Published patent application 20020065698 relates to a computerized method for managing a plurality of mobile assets, the method comprising: collecting data regarding each of a plurality of mobile assets; processing the data to develop historical information regarding actual usage of each mobile asset, said actual usage being arranged in a plurality of operational modes of the asset, each of said operational modes being indicative of a respective state of health of said asset; and distributing the information via a global information network.

U.S. Published patent application 20030135304 relates to a system for managing transportation assets. The system provides for dynamically (re)computing a trip route based on a real-time updateable stochastic model of a transportation network. The system includes an experience based database for storing a dynamic map data, passive data gatherers that periodically update the experience based database and a processor for (re)computing a trip route based on the experience based database and the stochastic model as influenced by the real-time transportation network data.

Published U.S. patent application 20020087488 relates to a server company that can track expenditures for a client company's individual vehicles and fleets of vehicles. The server company can automatically take care of paying the bills relating to outside service repairs from multiple vendors and forward a single itemized bill to the client company. The server company can also notify the client company regarding usage characteristics of various types of vehicles, expenditure trends, and even notify the client company when a vehicle needs routine maintenance. The invention reduces the expenditures a client company associates with maintaining a vehicle fleet, whether the vehicles are leased or owned by the client company.

Published U.S. patent application 20020082893 relates to a product delivery system that moves products from manufacturing plant to destination. Particularly applicable to the delivery of vehicles from vehicle assembly plants to dealerships, the system utilizes a centralized management organization overseeing independent entities in a delivery network, and provides a management team with improved visibility of and improved tools for operating the network, such as a tracking system by which managers in many parts of the network have access to the status of individual products and network facilities, a simulation tool by which managers can test scenarios for the purpose of changing product routing plans based on predicted capacity and bottlenecks, and a planning tool that can facilitate preparation of product routing plans in response to information from the other tools. The system also uses feedback from the delivery network to influence the sequence in which the products are manufactured.

U.S. Published patent application 20030229559 relates to an asset management platform. The asset management platform (AMP) processes messages from mobile assets to enable data-driven monitoring and management of the assets. The mobile assets transmit messages to the AMP specifying the assets' current locations and other information. Modules in the AMP normalize and augment the messages using state information and other data stored in a database. A router routes copies of the messages to multiple destinations, including applications and a business operations middleware (BOM) module. The BOM includes queues for holding messages of different types and subscribers for processing the messages in the queues. An event-action subscriber processes messages as specified by event-action rules. The event-action rules provide flexible and extensible asset tracking, fleet management, and notification capabilities.

U.S. Pat. No. 6,611,755 relates to a fully implemented fleet tracking system having many different locator and information systems for monitoring fleets and individual carriers in fleets. There are extensive disclosures of software, hardware, and system functions that are incorporated herein by reference to provide technical detail assisting in the support of enablement of the practice of the present invention.

U.S. Pat. No. 6,430,496 relates to a fully automated vehicle dispatching, monitoring and billing system. There are extensive disclosures of software, hardware, and system functions that are incorporated herein by reference to provide technical detail assisting in the support of enablement of the practice of the present invention.

Published U.S. patent application 20040225624 describes a cooperative system and an associated method are provided for resolving a distressed shipment during transport by a carrier, where the distressed shipment includes one or more parcels rendered temporarily undeliverable by an exception event while in transit from a shipper to a consignee. The inventive method involves the shipper in the task of contacting the consignee for the additional information necessary to resolve the shipment. The system creates a cooperative of participating shippers and carriers, working together to complete a shipment and thereby avoid the delay and expense associated with a premature or unnecessary return.

Published U.S. patent application 20030084125 describes an integrated exchange system for posting and reviewing shipping demand specifications and carrier availability information permits efficient shipper-to-carrier and/or carrier-to-carrier exchanges. The integrated exchange system finds matches between shipping demands and carrier availability and notifies the users of a match. Furthermore, the integrated exchanges system stores the shipping demand specifications and carrier availability information in a database and prepares various reports in response to a user request by using the database. In one embodiment, the integrated exchange system includes a monitoring unit that monitors the location of carrier vehicles and updates carrier availability information. In this embodiment, a carrier vehicle contains a location determining unit and a wireless modem. Additionally, the integrated exchange system can employ a standardized interface that facilitates data transfers from partner databases.

Each of these cited background references above are herein incorporated by reference to provide background support for technology, including components, systems, operation parameters, software, language, codes and other aspects of practice that can be incorporated into the practice of the present invention.

### SUMMARY OF THE INVENTION

A computer-based system monitors economic performance within a fleet of carriers comprising components of a communication network that provides information regarding at least individual carriers within the fleet of carriers to a processor; a processor that contains a software program that:
tabulates at least some of the information to provide a resource of economic performance within the fleet of carriers;
enables graphic representation of at least some measures of the economic performance; and
enables viewing of metrics including at least two parameters for evaluating the economic performance of a specific carrier.
   The processor may automatically evaluate individual carrier metrics and automatically alerts a designated party of failure to operate within acceptable operating tolerances. The processor may also provide signals to a display unit that receives information from the processor that automatically displays reports that are key performance indicators.

At least two parameters for evaluating economic performance may be selected, on a non-limiting basis from the group consisting of total number of orders, number of electronic orders, order accuracy, revenue/truck, variance in individual carrier performance, settlement status, idle truck count, specific carrier subset performance, invoicing status, reporting status, legal performance status, planned orders, started orders, dispatched orders, available orders, percentage of on-time delivery for specific carrier, load performance of specific carriers for completed trips, number of empty miles/total miles, number of cancelled orders/total orders, number of driving hours/order, number of driving hours/specific carrier per day, week or month, average speed/specific carrier, and number and/or value of legal citations/specific carrier.

### BRIEF DESCRIPTION OF THE FIGURES

FIG. 1 shows a screen shot of an accessed display of an accessed interactive screen for reviewing monitored carrier fleet performance.

FIG. 2A shows a screen shot of Order-based Metrics.

FIG. 2B show a screen shot of Metric categories.

FIG. 3 shows a screen shot of Metrics evaluating Orders Performance.

FIG. 4A shows a screen shot of a graph of individual carrier performance as revenue/truck.

FIG. 4B shows an icon for accessing one metric of individual truck performance.

FIG. 5 shows a screen shot of a Report Card for individual truck performance.

FIG. 6 shows a screen shot of an interactive screen for accessing various options available through the system of the invention.

FIG. 7 shows a screen shot of an interactive screen enabling access to various metric performance characterization evaluations.

FIG. 8 shows a screen shot of an interactive access screen for Menu Section Configuration.

FIG. 9 shows a screen shot of an interactive screen for Metric Configuration and Metric categories accessed through the screen shot of FIG. 8.

FIG. 10 shows a screen shot of a Metric Configuration accessed through the screen shown in FIG. 9.

FIG. 11 shows a screen shot of a Metric Parameter Configuration accessed through the screen shown in FIG. 10.

FIG. 12 shows a screen shot of a Metric item Configuration screen.

### DETAILED DESCRIPTION OF THE INVENTION

In the description of the present invention, certain terms will be used that tend to be standard within the field of the invention, yet which can benefit from additional definition or explanation.

“Software”, as used herein, includes but is not limited to, one or more computer readable and/or executable instructions that cause a computer, computer component and/or other electronic device to perform functions, actions and/or behave in a desired manner. The instructions may be embodied in various forms like routines, algorithms, modules, methods, threads, and/or programs. Software may also be implemented in a variety of executable and/or loadable forms including, but not limited to, a stand-alone program, a function call (local and/or remote), a servelet, an applet, instructions stored in a memory, part of an operating system or browser, and the like. It is to be appreciated that the computer readable and/or executable instructions can be located in one computer component and/or distributed between two or more communicating, co-operating, and/or parallel processing computer components and thus can be loaded and/or executed in serial, parallel, massively parallel and other manners. It will be appreciated by one of ordinary skill in the art that the form of software may be dependent on, for example, requirements of a desired application, the environment in which it runs, and/or the desires of a designer/programmer or the like.

A “metric” is a basis of measurement that can be used alone or in combination with other metrics or factors to determine costs, profits, benefits or data useful in an economic analysis of the performance of a carrier or fleet. Certain specific metrics may be identified as key performance indicators as they may be primary bases for determining economic performance, such as percent capacity filled/mile; dollars per mile for fuel; down time; and the like. Sets of metrics or sets of key performance indicators may be grouped to be displayed at the same time.

An “operable connection,” “communication link,” “information connection” and the like (or a connection by which entities are “operably connected”) is any connection (wired or wireless) in which signals, physical communication flow and/or logical communication flow may be sent and/or received. Usually, an operable connection includes a physical interface, an electrical interface, and/or a data interface, but it is to be noted that an operable connection may consist of differing combinations of these or other types of connections sufficient to allow operable control.

“Data store” refers to a physical and/or logical entity that can store data. A data store may be, for example, a database, a table, a file, a list, a queue, a heap, and so on. A data store may reside in one logical and/or physical entity and/or may be distributed between two or more logical and/or physical entities.

The invention may be generally described as a system for monitoring economic performance within a fleet of carriers. The system may comprise a communication network that provides information regarding at least individual carriers within the fleet of carriers to a processor and a processor that contains a software program. The program should be able to tabulate at least some of the information to provide a resource of economic performance within the fleet of carriers; enable graphic representation of at least some measures of the economic performance; and enable viewing of metrics including at least two parameters for evaluating the economic performance of a specific carrier. The system should also contain a display unit that receives information from the processor and that automatically displays reports that are key performance indicators (e.g., metrics or specified metrics). The metrics may include at least one metric selected from the group consisting of order management, dispatch status, invoice status, settlement status and reporting status. The at least two parameters for evaluating economic performance may be selected from the exemplary, but non-limiting group consisting of total number of orders, number of electronic orders, order accuracy, revenue/truck, variance in individual carrier performance, settlement status, idle truck count, specific carrier subset performance, invoicing status, reporting status, legal performance status, planned orders, started orders, dispatched orders, available orders, percentage of on-time delivery for specific carrier, load performance of specific carriers for completed trips, number of empty miles/total miles, number of cancelled orders/total orders, number of driving hours/order, number of driving hours/specific carrier per day, week or month, average speed/specific carrier, and number and/or value of legal citations/specific carrier.

The invention may also be described as a method for automatically reviewing management reports for fleet transportation systems and displaying those reports or providing alarms or alerts as to specific types of deviations from predetermined standards on individual metrics or key performance indicators. The method may comprise logging onto a website, selecting specific reporting criteria related to economic performance, and a processor providing observable data that are automatically generated and automatically refreshed with respect to the selected specific reporting criteria. The observable data may be selected from amongst available formats including at least specific quantitative performance, scholastic or quantitative grading and graphs; and the observable data is sent to a display unit that receives information from the processor that automatically displays reports that are key performance indicators. In this type of method, the specific reporting criteria may be selected from among at least two parameters selected from the group consisting of order management, dispatch status, invoice status, settlement status and reporting status. Again, the processor automatically evaluates individual carrier metrics and automatically alerts a designated party of failure to operate within acceptable operating tolerances. The specific reporting criteria may be selected from among a non-limiting list of at least two parameters selected, for example, from the group consisting of total number of orders, number of electronic orders, order accuracy, revenue/truck, variance in individual carrier performance, settlement status, idle truck count, specific carrier subset performance, invoicing status, reporting status, legal performance status, planned orders, started orders, dispatched orders, available orders, percentage of on-time delivery for specific carrier, load performance of specific carriers for completed trips, number of empty miles/total miles, number of cancelled orders/total orders, number of driving hours/order, number of driving hours/specific carrier per day, week or month, average speed/specific carrier, and number and/or value of legal citations/specific carrier. The method is useful for all forms of carriers, such as cabs, military vehicles, ice cream trucks, trains, passenger planes, cargo planes, and the like, but is particularly useful where the carriers are trucks.

To better serve the needs for speedy evaluation by managers, whose job it is to maintain economic output for the carriers, it is advantageous to provide reported automatic displays in the form of scholastic displays. A scholastic display is a symbol or number with no absolute relationship to a specific measured value, but is representative of relative rank. For example, “on a scale of 1 to 10,” and typical school grades of A, B, C, D and F are well known scholastic values. An A may be related to a range of values, e.g., 98-100% of optimal goals, and yet is a scholastic value, as opposed to 99.4. Scholastic values can be more informative since it has been designed and selected to relate to a predetermined level of performance. For example, an absolute value of 65 for average miles/hour may be the optimal goal and would be rated as an A, yet a higher absolute number of 87 for percent space filled per trip or yearly satisfied invoices would be on the order of a C or D, respectively. By providing automatically refreshed and historical values for comparison of the metrics or key performance indicators in scholastic format, the administrator can rapidly sift through the data with assurance of the qualitative accuracy of his review, without having to analyze the impact of specific measured values. Upon identifying specific scholastic values that have caught the administrator's attention, those metrics or key performance indicators may be specifically expanded in disclosed content to identify the specific level of performance that is worthy of attention.

The system for monitoring economic performance within a fleet of carriers may also comprise a communication network that provides information regarding at least individual carriers within the fleet of carriers to a processor. The processor may contain a software program that tabulates at least some of the information to provide a resource of economic performance within the fleet of carriers; enables graphic representation of at least some measures of the economic performance; and enables viewing of metrics including at least two parameters for evaluating the economic performance of a specific carrier. The processor may automatically evaluate individual carriers, subsets of carriers, sets of carriers or entire fleets of their respective metrics and automatically alert a designated party (e.g., local administrator, fleet administrator, dispatcher, or combinations of these or others with a need to know) of failure to operate within acceptable operating tolerances.

With an automatic alert system, and the capability of the contacted party quickly addressing any low performance issues on a rapid response basis, the economic performance of individual carriers, subsets, sets and fleets of carriers can be maintained at a higher performance level. The use of the system for subsets of fleets (e.g., carriers within specific geographic areas, which might be uniformly affected by weather conditions; carriers within regions with significant fuel price fluctuations; only Extra Wide load carriers; furniture carriers; and the like) can be advantageous for administrators and drivers for normalizing comparisons. For example, is there is a fuel shortage in one region and a glut in another, significant variations in fuel costs should not advantage or disadvantage ranking of individual carriers, and exceptions to scholastic grades in specific regions can be made.

The system for reliably reporting information to a central data collection system may be based on the Internet. The Internet is a collection of computer networks that allows computer users to share files and other computer resources. Each computer connected to the Internet has a unique address whose format is defined by the Internet Protocol (“TCP/IP”). The Internet includes a public network using the TCP/IP and includes two kinds of computers: servers, which provide information and documents; and clients, which retrieve and display documents and information for users. As will be appreciated by those of ordinary skill in the art, as used throughout this specification the term “client” refers to a client computer (or machine) on a network, or to a process or programs, such as Web browsers, which run on a client computer, in order to facilitate network connectivity and communications. This specification will use the term “individual” or “user” when referring to a person using a client computer to access the server and enter usage information. Similarly, the term “server” will be used throughout this specification to refer to a server computer or computer system on a network, including the database attached to the server for storing information.

The “World Wide Web” (“Web”) is that collection of servers on the Internet that utilize the Hypertext Transfer Protocol (“HTTP”). HTTP is a known application protocol that provides users access to resources, which may be information in different formats such as text, graphics, images, sound, video, Hypertext Markup Language (“HTML”), as well as programs. HTML is a standard page description language which provides basic document formatting and allows the developer to specify “links” to other servers and files. Links may be specified via a Uniform Resource Locator (“URL”). Upon specification of a link by the user, the client makes a TCP/IP request to a Web server and receives information, which may be another “Web page” that is formatted according to HTML. Users can also access other pages on the same or other servers by following instructions on the screen, entering certain data, or clicking on selected icons.

Servers run on a variety of platforms, including UNIX machines, although other platforms, such as Windows 95, Windows NT, and Macintosh may also be used. The systems may be hard-connected (e.g., through wires, cables, lines, optical fibers or other physical transmissions) or may be unwired, using electromagnetic transmissions) to convey information, signals and data. Computer users can view information available on servers or networks on the Web through the use of browsing software, such as Netscape Navigator, Microsoft Internet Explorer, Mosaic, or Lynx browsers. A typical Web page is an HTML document with text, “links” that a user may activate (e.g. “click on”), as well as embedded URL's pointing to resources, such as images, video or sound, that the client may activate to fully use the Web page in a browser. Furthermore, icons are present which a user clicks on to submit usage information to the server, or to request information from the server. In some situations, these resources may not be located on the same server that provided the HTML document to the client. Furthermore, HTTP allows for the transmission of certain information from the client to a server. The server can then post this information on its web site, forward it on to another user or server, or save it to a database for later use.

The software used in the presently contemplated system and the additional hardware and software components described below, are preferably written in a source code language providing easy transport between computing platforms. One particularly suitable source code language is BBx Business Basic, sold by Basis International of Albuquerque, N.Mex. This language provides portability of source code between any one of (a) a PC/DOS/Windows/Windows95 stand alone or Novell Netware server environment using BBx for DOS/Novell; (b) a Unix network using serial terminals using BBx for Unix (SCO/AIX/Etc.); (c) a Windows for Workgroups environment with or without a Windows NT server using BBx for Windows for Workgroups. Furthermore, using the BBx TCP Data Server software, any or all of the above can be connected in a wide-area or Internet network.

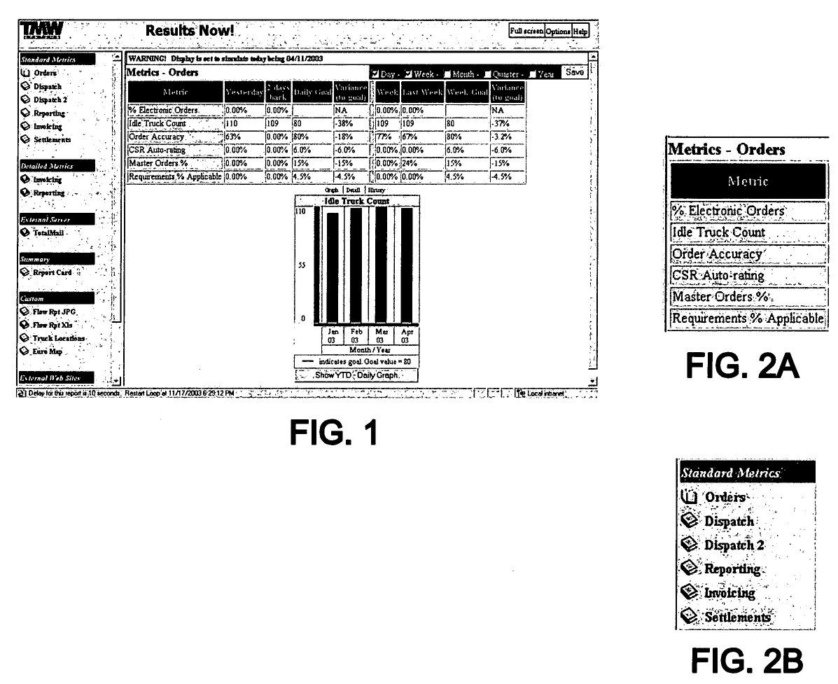

Suitable Automatic Vehicle Locator systems can be purchased from various vendors including DCS, Inc., Teletrak, American TriTech, and EAI; these AVL systems either include low-level communications protocols of the kind illustrated below in FIGS. 3K-1 to 3R-2 or will revise their AVL systems to support such communications.

It should be noted that a system other than the AVL may be used to support the communications between the dispatching systems and the AVL; for example, there are presently being introduced satellite paging-response systems which permit two way communications between mobile pagers and a central office via direct satellite communications. These systems could be used to transmit and receive the information discussed below.

It is contemplated that a given automated dispatching system may include multiple communications processes, dispatching processes and vehicle monitoring processes, running independently in networked computing systems. The source language used for programming this system must include facilities for locking individual database records for a multiprocessing environment—such record locking is provided by the BBx Business Basic language described above. The graphs, charts and operations of each of the communications, dispatching and vehicle monitoring processes will be elaborated upon with an understanding that multiple processes may be in simultaneous operation at any given time and processing dispatching records in the central server simultaneously. It will also be understood that human dispatchers, because they are freed from most dispatching tasks, will monitor the overall operation of the automated dispatching system and determine whether an alert situation has occurred in any of the communications, delivery, accounting, dispatching or vehicle monitoring phases of operations, and if so may initiate additional recovery adjustment, to provide added computing time to the task which is experiencing an alert.

To effectively utilize the vast amount of data that may be available regarding a fleet of mobile assets, the output of the analysis of such data must be effectively displayed and conveyed to one or more interested users. An Internet web page is an effective means for communicating such data and information. An Internet web page may be updated to reflect the performance reports, operating statistics, and/or current location map for the fleet of mobile assets. One or more such web pages may be utilized with appropriate hyperlinks to additional web pages. By nesting related web pages, the level of detail presented to the user may be controlled by that user. For example, a location map illustrating the current geographic location of each of the assets owned by a rail transportation company may include a hyperlink at the indication of the location of each of the locomotives. Such a map may also illustrate the location of service facilities. In the context of a fleet of trucks, a road map may be generated showing the location of each truck along with its route. By constructing such a map in a web site format, a hyperlink may be provided on the map for each mobile asset to connect the user to an interconnected nested web page including additional information regarding that particular vehicle. For example, while the location of the mobile asset may be seen on a map, by double clicking a cursor on the symbol for a single mobile asset, the speed, destination, route, cargo information, fuel level, driver information, and other operating information for that mobile asset may be viewed on nested web pages. One user, such as a customer of the transportation company, may only be interested in the location of the truck. Another user, such as a service technician employed by the railroad, may be interested not only in the location of the locomotive but also in the amount of fuel on board or other operating parameter. Any such users, can quickly obtain the information they need by a simple point and click operation using known Internet browser technology.

One embodiment of an element of the present invention is referred to as Results Now, a web-based, performance monitoring application that allows you to determine whether a company is meeting its daily, weekly, monthly, quarterly, and yearly business goals. The application consists of SQL-driven metrics that provide you with current snapshots of revenue, costs, and operational data that directly affect the company's profitability. It is installed and or accessible from a central supported location on the company's intranet so that it can be accessed internally via a browser. Based on its configuration, information is updated daily based on data recorded in TMWSuite™.

Certain ones of the at least two parameters for evaluating economic performance may be selected, on a non-limiting basis, have meanings that are apparent to those skilled in the art. However, some of the terms may need further explanation, as presented directly below, or as explained elsewhere herein. This invention is further described in the “Reference Guide for TMWSuite™ Results Now Metrics,” which is incorporated herein by reference and attached to this document. Order accuracy, for example, may include (but not necessarily be limited to) original order-form filling out, proper loading, proper delivery time, proper delivery location, and the like. The revenue/truck may be based on various time or event parameters, such as per day, per week, per month, per order, per trip, and the like. Variance in individual carrier performance can be based upon any standard measure of quality, both substantive and subjective, including driving complaints, customer evaluations, goods damage, comparative gas costs, and the like. Carrier subset performance can be used to assure that different types of carriers are not compared, so that cooler trucks, temperature control trucks, supersize trucks, and other device specialty vehicles are not compared across natural differentiation lines. Reporting status would include any required direct notice compliance for specific classes of goods at required intervals, indication of weighing status, intermediate delivery notice, and the like. Legal performance status would include all such reporting of traffic violations, legal interdictions/searches, weight stops, and now even compliance with mandated minimum sleep requirements for drivers, and the like. This reporting would probably have to be done on at least a day-to-day basis. Planned orders, started orders, dispatched orders, and available orders are self-explanatory, as are the percentage of on-time delivery for specific carriers, load performance of specific carriers for completed trips, number of empty miles/total miles, number of cancelled orders/total orders, number of driving hours/order, number of driving hours/specific carrier per day, week or month, average speed/specific carrier, and number and/or value of legal citations/specific carrier.

Each metric employs stored procedures that consist of the following:

A Set of Standard, Configurable Parameters.

Parameters are restrictions that allow the user to filter data according the User reporting requirements. Although the user can run a metric with just the standard parameter set, additional parameters are available for some metrics. Configuration options for these parameters allow the user to customize the metric so that it gives the user the data the user wants. If needed, the user can create and use multiple variations of a metric.

Defined Calculations.

A metric is a value based on defined calculations with configurable parameters. This can be a dollar amount (Revenue/Day), a number (Active Trucks/Day), or a percentage (Deadhead Percentage/Day). Metrics are rolled up into weekly, monthly, quarterly, and yearly values, but are still averaged per day. The application compares the user's established business goals with real-time data so that the user knows how close to plan the user's business is operating.

In addition, some metrics provide the user with the ability to set up alert thresholds. When a metric result falls below the acceptable level, as specified by the alert threshold, the system provides the user with an alert to make the user aware of the problem immediately. This allows the user to manage by exception—the user's attention is needed only when business practices deviate beyond a designated allowance from business goals.

The following subsections provide an overview of how the application displays data:

| | |
|---|---|
| Overview of the Results Now screen layout | 17 |
| Links | 17 |
| Display of report data | |
| How metric data is displayed | 18 |
| Spreadsheet-style charts in summary or detail form | 18 |
| Graphs | 18 |
| Report card | 19 |
| Looping through Results Now pages automatically | 19 |
| Viewing metric categories and parameters | 20 |
| Non-Limting Examples of Metric categories | 20 |
| Order Management | 20 |
| Dispatch | 21 |
| Invoicing | 21 |
| Settlements | 22 |
| Reporting | 22 |
| User-defined metric parameters | 22 |

Overview of the Results Now Screen Layout

When the user access Results Now, the user sees a screen similar to the one shown in FIG. 1.

Links are grouped under these headings, which are listed along the left side:

Links

| | |
|---|---|
| Standard | Listing of categories that consist of metrics that provide |
| Metrics | summary data that is rolled up by day, week, month, quarter, |
| | or year. |
| Detailed | Listing of categories that consist of detailed listing of data. |
| Metrics | |
| External | Results Now can pull information from multiple databases. |
| Server | Item(s) under this heading identify database(s) that reside on a |
| | different server from the TMWSuite ™ database. |
| Report | Summary results for each metric can be assigned letter |
| Card | grades A, B, or C, and so on, or they can be displayed as |
| | percentages or dollar amounts. Grades for all metrics are listed |
| | on a single screen for a high level view of your company's |
| | performance. |
| Custom | Links to your company's internal reports programs, and |
| | intranet pages. |
| External | Links to external web pages. |
| Web Sites | |

The links are always visible and are accessible from any Results Now screen.

Display of Report Data

Report data is shown in the right pane of the Results Now page in FIG. 1. It represents a metric that belongs to a category under the Standard Metrics heading. The active category is denoted by an open book icon, as shown in FIG. 2a. By default, the active metric in that category would be shown in a unique color or highlighting, as illustrated in FIG. 2B.

The information shown in the right pane changes when:
The user can click on a different link listed along the left.
The user can allow the system to loop through various Results Now pages automatically based on pre-defined time intervals.
The user can click the Options button in the upper right to access metric configuration screens.
   How Metric Data is Displayed

The user can see data in any of these forms:
Charts
Graphs
Report card format.

There are two other views that can be provided, and are provided on the present system:
I. “This time frame/Last time frame”

This means, Yesterday/Today, Last Week/This Week, Last Month/This Month, Last Quarter/This Quarter, Last Year/This Year. This offers a direct comparison on a selected time-line basis between different time periods.
II. “Timeline”

This selection shows the last “X” time frame for a category of metrics, and provides a time frame rollup (not including the current “to-date” time frame, and provides a variance against the goal to the time frame rollup.

Spreadsheet-Style Charts in Summary or Detail Form

In the upper portion of a Metrics page, report information is summarized in chart form by day, week, month, quarter, and/or year so that the user can compare current results with the user's company's past performance. Some metrics also provide a listing of detailed data. These links are shown below the summary:
Detail: Allows the user to access a listing of data recorded for yesterday.
History: Provides detailed data for the entire year to date.

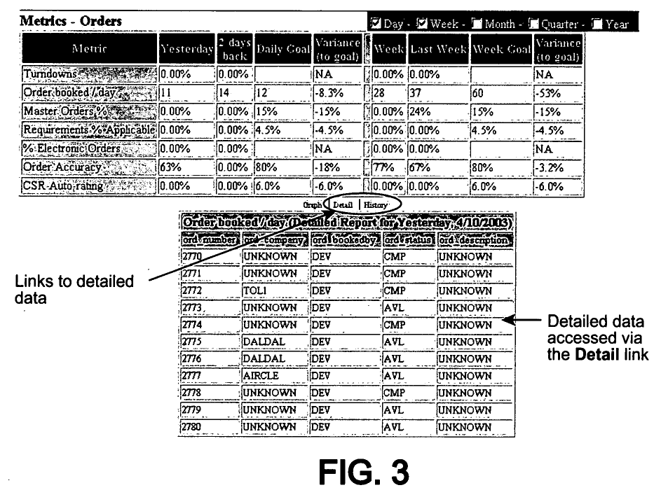

This information display is shown in FIG. 3.

Graphs

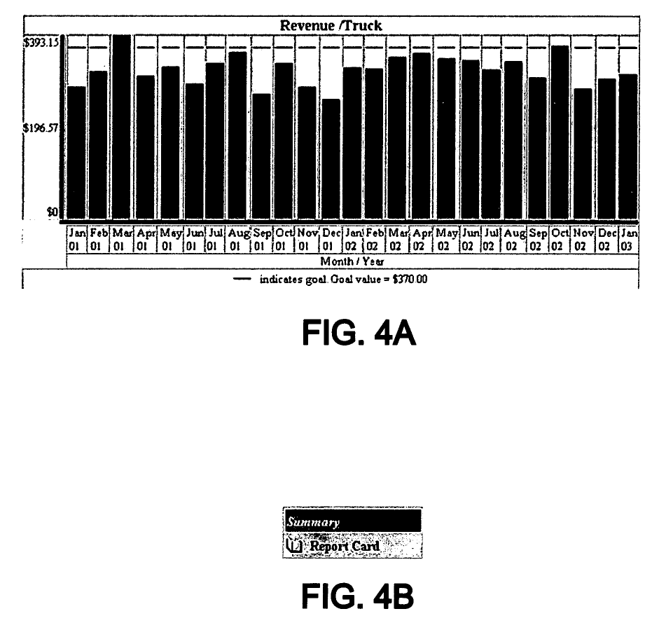

The detail in most if not all graphs can be viewed for any day that exists in history. However, viewing a day in history may yield a different computed result than the result contained in the history table for that day, because of subsequently corrected or changed data. To access information shown in graph form, click the Graph link shown below a metric's summary. Graphs display metric results and overlay them with pre-determined goals for an at-a-glance view of data trends. An example of a specific available graph is shown in FIG. 4b, for a graph of Revenue/Truck. Report card format.

The user can roll all metric results up into a report card format. Based on parameters the user specifies, results for each metric are assigned letter grades A, B, or C, and so on, or they can be displayed as percentages or dollar amounts. The report card format allows the user to see all metric results at the same time, enabling the user to determine which areas of the business need immediate attention. To see the report card for the metrics set up for a specific company, click the Report Card link on the left of the Results Now page, as shown in FIG. 4B.

Report Card

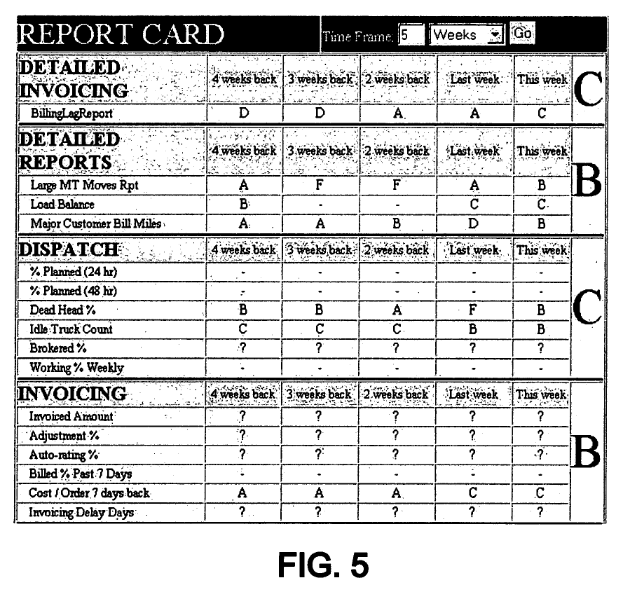

A report card sample is shown in FIG. 5.

Looping through Results Now Pages Automatically

Unlike a typical report, Results Now loops through different pages showing summarized information. The result is a customized slide show of data that reflects the current state of the user's business. This design makes the application appealing to run from a large screen monitor in a highly visible area, making employees aware of the performance of the business. Security can be added to prevent unauthorized access to certain information.

The performance monitoring of business metrics is a subset of a shell, or portal, which can be customized with other web pages. For instance, a page included with Results Now (i.e., a page included in the loop) could display current weather maps from www.weatherchannel.com. External pages, internal pages, and Excel reports also can be included in the looping routine by changing the configuration through the user interface. In addition, the user can set up links to pages that are not part of the loop. The company web site, main intranet site, or a popular search engine is a good candidate for this.

Viewing Metric Categories and Parameters

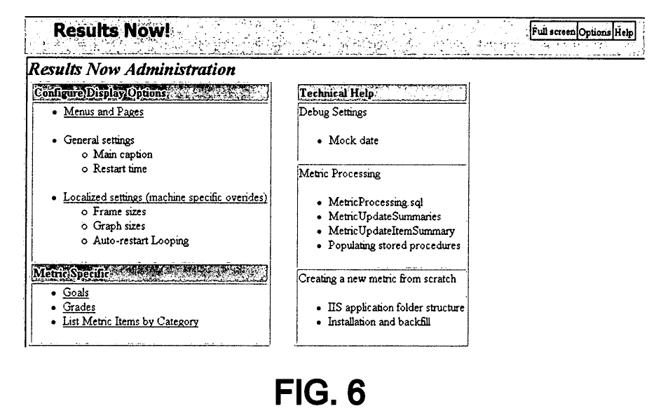

The Results Now Administration screen lists options that the user can use to set or review metric configurations. To access this screen, click Options in the upper right of any page, as shown in FIG. 6.

User-definable options are listed along the left side under the headings Configure Display Options and Metric Specific.

Non-Limiting Examples of Metric Categories

By default, metrics may be grouped under these or other categories:
Orders
Dispatch 1
Dispatch 2
Invoicing
Settlements
Reporting

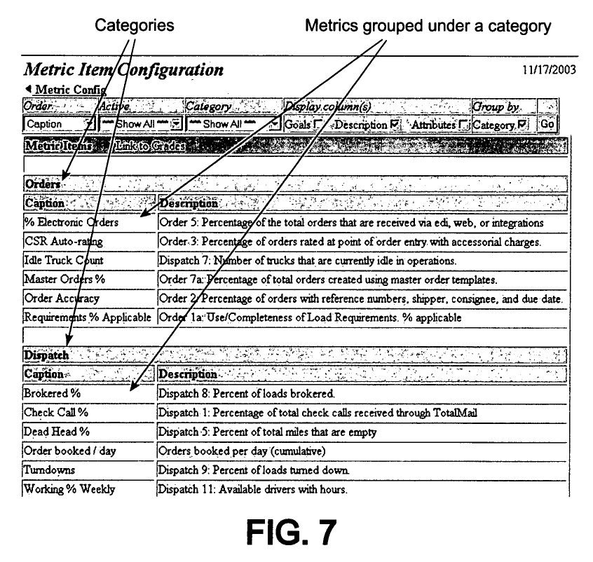

The user can change a metric's classification. In addition, the user can create your own categories. To view the metrics that make up the categories used by the user's company, click the List Metric Items by Category link on the Results Now Administration screen. The Metric Item Configuration screen is shown. This illustration shows a partial listing of metrics and the categories to which they belong being shown in FIG. 7. Listed below are the categories and metrics that come pre-loaded with the application:

Order Management

| Metric | Description |
|---|---|
| Requirements | Use/Completeness of Load Requirements. |
| Percentage | % applicable, % used. |
| Order Accuracy | Percentage of orders with reference numbers, shipper, |
| | consignee, and due date. |
| CSR Auto Rating | Percentage of orders rated at point of order entry with |
| Percentage | accessorial charges. |
| Percent Electronic | Percentage of the total orders that are received via |
| Orders | EDI, web, or integrations. |
| CSR Staffing | Orders to Staff. |
| Leverage | |
| Orders booked | Orders booked per day. |
| per day | |
| Master Orders | Percentage of total orders created using master |
| Percentage | order templates. |

Dispatch

| Metric | Description |
|---|---|
| Check Call Percentage | Percentage of total check calls received via |
| | TotalMail. |
| Revenue Per Mile | Total revenue per traveled mile. |
| Percent Planned | Percent of orders that are planned 24 out. |
| (24 Hours) | |
| Percent Planned | Percent of orders that are planned 48 hours out. |
| (48 Hours) | |
| Dead Head % | Percent of total miles that are empty. |
| Revenue per Truck | Revenue productivity per truck dispatched |
| Idle Truck Count | Number of trucks that are currently idle in |
| | operations. |
| Brokered Percentage | Percent of total loads brokered. |
| Turndowns | Percent of loads accepted turn down. |
| Working Percentage | Available drivers with hours. |
| Percent Update Macros | Percentage of macros that update the system. |

Invoicing

| Metric | Description |
|---|---|
| Adjustment Percentage | Percent of total bills that require adjustment after |
| | invoicing. |
| Auto-rating Percentage | Percentage of total orders auto-rated at invoicing |
| Un-Billed Percentage | Percent of total bills that are not billed. |
| Cost/order 7 days back | Cost/order 7 days back |
| Billed percentage | Billed percentage 7 days back |
| 7 days back | |
| Invoice delay days | Average number of delay days from the time |
| | invoices are sent |
| Invoiced amount | Dollars invoiced |
| Billing Effort | Billing resources to the number of bills. |
| Settlements | |
| Adjustment Percentage | Percent of total settlements that require |
| | adjustment after releasing to the driver |
| Settlement Effort | Staff to driver ratio |
| Driver Pay Trend | Number of drivers with a downward pay trend |
| Count | for 3 pay periods |

Reporting

| Metric | Description |
|---|---|
| Daily Revenue | Daily revenue based on completed deliveries. |
| Daily MT Mileage | Total empty miles run on company tractors for the |
| | operating day |
| Tractor Utilization | Total number of miles per active tractor |
| Operating Ratio | Total operating expenses divided by the total |
| | revenue |
| Miles per Tractor | Miles traveled per tractor |
| On-Time Service | Number of on-time deliveries divided by the total |
| | number of deliveries. |

User-Defined Metric Parameters

In the Results Now application, there is a configuration page for each metric. The parameters entered on this page determine the data used to perform calculations for a particular metric.

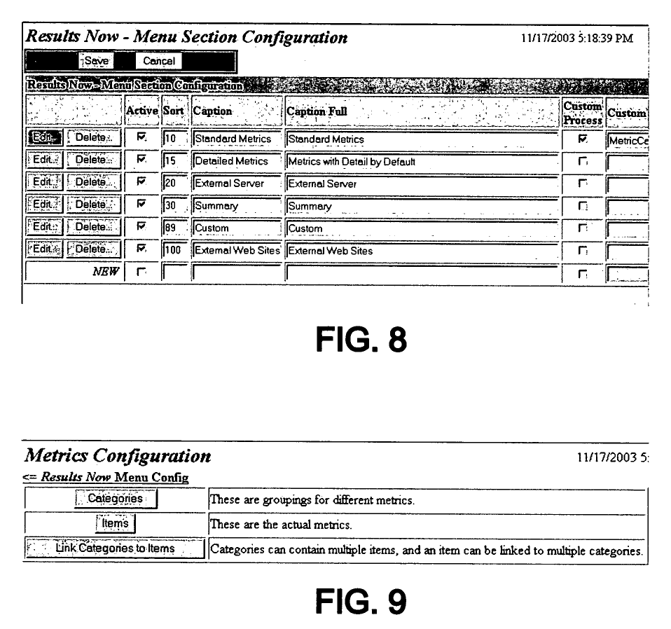

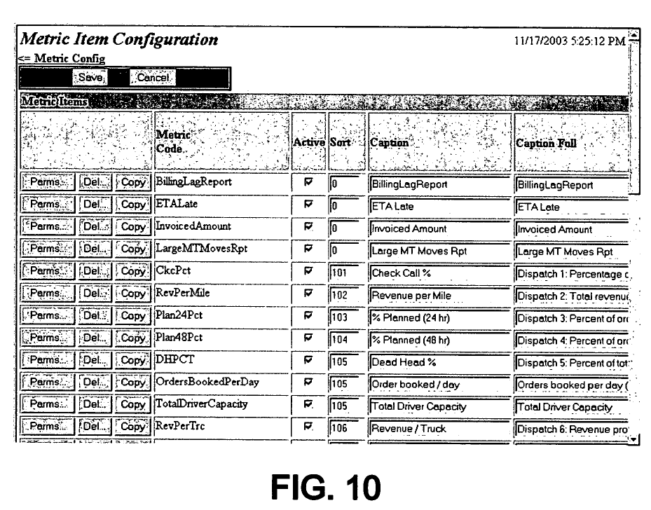

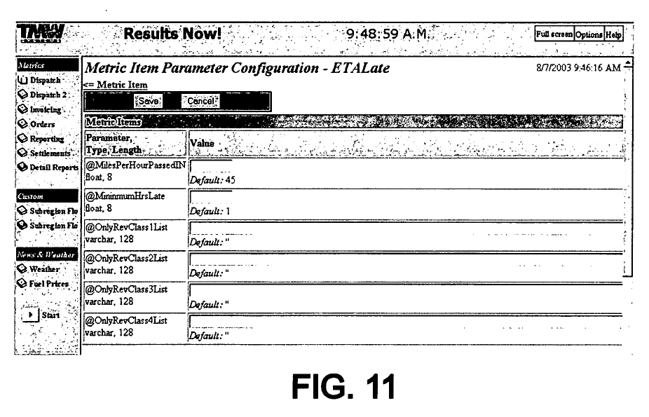

To access the configuration page for a metric:
1. Click Options in the upper right. The Results Now Administration screen is shown.
2. In the Configure Display Options box, click the Menus and Pages link.
3. The Menu Section Configuration screen is shown in FIG. 8.
4. To the left of the line that says Standard Metrics, click Edit. The Menu Config screen is shown in FIG. 9.
6. Click Items. The Metric Item Configuration window is shown in FIG. 10.
7. Click the Parms button to the left of the metric for which you want to view or modify restrictions. The Metric Item Parameter Configuration screen is shown IN FIG. 11.

This illustration in FIG. 11 shows a listing of parameters for a metric.

Parameters are listed in the first column. In the Value column, the user can specify the restriction wanted to impose for the parameter, if it differs from the default value.

For information on metrics parameters for the user's TMW product, see the applicable Reference Guide for Results Now Metrics.

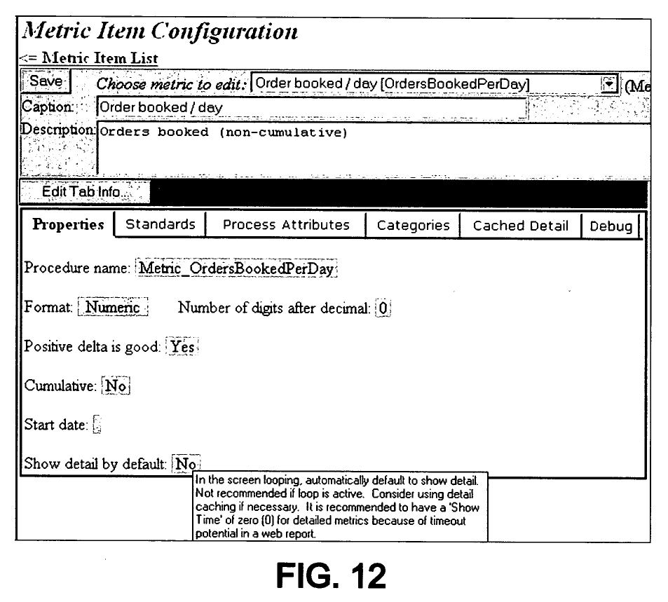

Configuring Metric Attributes. These options can be viewed in the configuration screen shown in FIG. 12. Within this screen is the capability of adjusting and selection amongst various metric attributes such as:
I. Metric Properties
   Corresponding SQL stored procedure name
   Format (either numeric, percentage, or currency)
   Number of digits after the decimal
   Is positive delta good
   Cumulative—for value based metrics only.
      Example: Total Orders Booked (cumulative) vs. Orders Booked per day (non-cumulative). The weekly “Total Orders Booked” would be a sum of all the orders booked for that week. Whereas, the weekly “Orders Booked per day” would be a sum of all the orders booked for that week divided by 7.
      Start date: The date at which to start keeping values in history. This is used for validation of data. This aspect may show detail by default: for viewing.
II. Standards
   Grades
   Goals
   Alerts
III. Process Attributes
   Active process: If this response or display is “NO”, then do not process this metric.
      Processing Sort Order

Refresh History: If last process date is older than X days, then rerun for Y days back. These values may be established in the original program or modified by each user.

The typical use for this is to set X=0 (zero), and Y=14. This will rerun processing for the previous 14 days back every time the metric gets processed.
IV. Category assignments
V. Cached detail: Is supported, but no metrics currently use it.

This allows for detail to be cached for a day when processing runs.

As earlier mentioned, this result may be attained by equipping each of the vehicles M₁ . . . Mₙ with an onboard GPS receiver GPS-R₁ . . . GPS-Rₙ and a data communications satellite terminal T₁ . . . T₁, enabling semi-continuous reporting via the dotted-line paths (“semi continuous”) of the maintenance vehicle/personnel to the common data processing center facility IPC that processes and stores the information on the vehicles E₁ . . . Eₙ. In accordance with the preferred embodiment of the present invention, this maintenance or service vehicles/personnel reporting occurs relatively frequently when the maintenance vehicle is in motion, as earlier mentioned, typically once every 4-6 minutes, for example, but much less frequently if the vehicle is stopped—say, for example, every 1-2 hours or so. The software that accordingly enables the maintenance vehicle displays “S” at D to the customer fleet maintenance managers, together with the vehicle equipment sites “X”, and, preferable together with the recent track Tr of the past recent movement of the vehicles.

The employment of the present invention, thus, is targeted at organizations with large vehicle services that need to keep track not only of their vehicular equipment in the field, but also of their service personnel, carriage and equipment, providing fully integrated tracking of the mobile vehicles and thereby allowing management personnel to synchronize the day's activities from a desktop or laptop computer, while satisfying the need for emergency repairs to “down” equipment machines in the field and monitoring of performance so that essentially near-real time performance can be adjusted.

Using state-of-the-art global positioning and geo-synchronous satellite communication techniques, as before detailed, the location of each and every vehicle in the fleet is plotted and updated on a minute-to-minute basis, linking and displaying vehicles on the same map display D so as to provide management with the tools to make quick, accurate, cost-effective, service-oriented decisions in short time and with a seamless overlay of both the fleet of working vehicles in the field and the service personnel working in the field available to maintain the same. When the manager receives any alert call, the manager can immediately make adjustments, including locating the closest vehicle and technician to that site for instant dispatch, bringing a locator map up on the screen that shows where equipment and personnel are located in virtually real time, and all done automatically 24 hours a day, seven days a week, and 365 days a year, via wireless communications. The user can zoom in as tight as the street locations or zoom back to reveal the entire city, county, state, country or even the entire world.

The system and processes of the technology described herein can be supported on a wide range of commercially available components, and the selection of such components is not as important as is the configuration of equipment and processes performed on the equipment. The following examples are merely exemplary lists and indications of specific commercially available components and specifications that might be among those selected by one skilled in the art in constructing a system according to the teachings provided herein. These guidelines and lists are not intended to be limiting in the practice of the invention but are further support of the generic teachings provided.

This system, particularly when utilized in motor vehicle applications, is capable of monitoring, storing, and transmitting data such as that described in detail above. These may also include the following: driver information, vehicle information, time, speed, latitude and/or longitude of the vehicle, direction of travel, state line crossing data, and mileage. Moreover, the data stored in the unit can be ported to a discretely accessible Internet data storage location either through a pager system for on line tracking or through the unique data card features of the system. Below are tables indicating exemplary specifications for various components that may be employed by the system.

EXEMPLARY SYSTEM OPERATING SPECIFICATIONS: GPS Module, such as a Motorola M12 ONCORE®. Communications througha Stellar Satellite module/Motorola Module Creata™ link 2XT for a pager. Any CPU having the necessary storage, processing and memory capacity, as indicated above and below, such as a processor containing and Intel 3, 4 or 5 Pentium® processor, including but not limited to a Dell, gateway, Hitachi, or Fujitsu orMotorola 32 bit embedded controller. The vehicle should contain an Inbuilt Memory, such as at least a 1 Mbyte Non-volatile memory for trip storage. The Data card memory size should be at least 128 kb (Expandable to 1 MB), but with the decrease in costs of memory, much higher capacity into Gigabyte range can be afforded. The Data card Interface should be compatibly designed for the at least 128 kb data card (upgradeable). The Data card reader/writer may be a stand-alone Mcore™ controller. Any convenient display my be used, with LED displays and associated support components preferred because of their low energy requirements. The Display may, for example, comprise a 2×16 LED display with LED back light. There should be a Key board (e.g., 4×4 matrix feather touch keypad). LED Indications may include Power LED, Card LED, Status LED, Serial port, and an RS232 serial port for PC interface for diagnosis purpose and Engine data, Parallel I/O, with Optional I/O lines available at request, Power supply, and 9 TO 36 VDC (Pager version) 9 TO 16 v VDC (Satellite version). The system may, as alternatives or additions to parameters described above include Data Log Parameters such as Driver ID, Driver name, License number, Vehicle ID, Route ID, UTC time, Stop time, Date Latitude, Longitude, Speed, Heading, direction, GPS, fix status, GPS status, Mileage, Fuel, added Price per gallon Type—bulk/retail, Starting odometer, Ending odometer, Vehicle stopped time, Break time, Driver hours of service. Programmable Driver ID parameters may ionclude Driver name, Driver license number, Driver License State, Route ID, Fuel added Price per gallon, Log period, Vehicle ID, Location ID, Passwords UTC offset, and Pager Number

EXEMPLARY GPS MODULE SPECIFICATION: I/O Messages Latitude, longitude, height, velocity, heading, time, such as through a Motorola binary protocol at 9600 baud, NMEA 0183 at 4800 baud (GGA, GLL, GSA, GSV, RMC, VTG, ZDA), a Software selectable output rate (continuous or poll) 3 V digital logic interface Second COM port for RTCM input. Power Requirements may be, for example, 2.8 to 3.2 V (dc), 50 mV p-p ripple (max). “Keep-Alive” BATT, External 1.8 V (dc) to 3.2 V dc, 5 μA Power (typical @2.7 V (dc) @ +25° C. Power consumption <0.225 W @ 3 V without antenna. Dimensions, 40.0×60.0×10.0 mm (1.57×2.36×0.39 in.). Weight: Receiver 25 g (0.9 oz). Connectors: Power/Data: 10 pin (2×5) unshrouded male header on 0.050 inch centers (available in right angle or straight configuration), RF, Right angle MMCX female (subminia-ture snap-on). Antenna Active micro strip patch Antenna Module Powered by Receiver Module at select-able 3 or 5 V. Antenna to Receiver Single coaxial cable with 6 db maxi-Interconnection mum loss at L1 (active antenna) Antenna Sense Circuit Antenna gain range 16 to 30 db. Operating Temperature, −40° C. to +85° C., Storage Temperature −40° to +85°, Humidity, 85% Relative Humidity at 85° C. Altitude: 18,000 m (60,000 ft.) maximum >18,000 m (60,000 ft.) for velocity <515 m/s (1000 knots), Standard Features Motorola DGPS corrections at 9600 baud on COM port, message for DGPS AT 2400, 4800 or 9600 baud on COM port two NMEA 0183 output Inverse DGPS support, and Backup power, Lithium battery backup.

TRANSMITTER SPECIFICATION: Frequency (1 MHz focus) e.g., 901-902 MHZ, RF power output (0.5 W, 0.75 W, 1.5 W and 2.0 W antenna port), Transmitting data bit rate may be 9600 bits per second (bps). Modulation: 4-level Frequency shift keying (FSK), Frequency stability: 1 ppm while transmitting. EXEMPLARY RECEIVER SPECIFICATIONS: Frequency, (e.g., 1 MHz range) 940-941 MHZ, sensitivity −115 dBms into SMA antenna connector. Receiving at a data bit rate of 6400 bps. Modulation: 4-level FSK, Channel spacing, 50 KHz.

Although the practice of the invention has been described with respect to the use of specific equipment, specific screen formats, and specific parameters, those with skill in the art can readily appreciate that these descriptions and examples are exemplary and are not intended to act as the basis for a limiting interpretation of the practice of the invention. Rather, these should be viewed as specific examples within a broad generic field of practice.

1. A system for monitoring economic performance within a fleet of carriers comprising:
a communication network that provides information regarding at least individual carriers within the fleet of carriers to a processor;
a processor that contains a software program that:
tabulates at least some of the information to provide a resource of economic performance within the fleet of carriers;
enables graphic representation of at least some measures of the economic performance; and
enables viewing of metrics including at least two parameters for evaluating the economic performance of a specific carrier; and
a display unit that receives information from the processor that automatically displays reports that are key performance indicators.

2. The system of claim 1 wherein the metrics include at least one metric selected from the group consisting of order management, dispatch status, invoice status, settlement status and reporting status.

3. The system of claim 1 wherein the at least two parameters for evaluating economic performance are selected from the group consisting of total number of orders, number of electronic orders, order accuracy, revenue/truck, variance in individual carrier performance, settlement status, idle truck count, specific carrier subset performance, invoicing status, reporting status, legal performance status, planned orders, started orders, dispatched orders, available orders, percentage of on-time delivery for specific carrier, load performance of specific carriers for completed trips, number of empty miles/total miles, number of cancelled orders/total orders, number of driving hours/order, number of driving hours/specific carrier per day, week or month, average speed/specific carrier, and number and/or value of legal citations/specific carrier.

4. A method for reviewing management reports for fleet transportation systems comprising logging onto a website, selecting specific reporting criteria related to economic performance, and a processor providing observable data that are automatically generated and automatically refreshed with respect to the selected specific reporting criteria,
wherein the observable data may be selected from amongst available formats including at least specific quantitative performance, scholastic or quantitative grading and graphs; and the observable data is sent to a display unit that receives information from the processor that automatically displays reports that are key performance indicators.

5. The method of claim 4 wherein the specific reporting criteria may be selected from among at least two parameters selected from the group consisting of order management, dispatch status, invoice status, settlement status and reporting status.

6. The method of claim 1 wherein the processor automatically evaluates individual carrier metrics and automatically alerts a designated party of failure to operate within acceptable operating tolerances.

7. The method of claim 4 wherein the specific reporting criteria may be selected from among at least two parameters selected from the group consisting of total number of orders, number of electronic orders, order accuracy, revenue/truck, variance in individual carrier performance, settlement status, idle truck count, specific carrier subset performance, invoicing status, reporting status, legal performance status, planned orders, started orders, dispatched orders, available orders, percentage of on-time delivery for specific carrier, load performance of specific carriers for completed trips, number of empty miles/total miles, number of cancelled orders/total orders, number of driving hours/order, number of driving hours/specific carrier per day, week or month, average speed/specific carrier, and number and/or of value legal citations/specific carrier.

8. The method of claim 1 wherein the carriers are trucks.

9. The method of claim 1 wherein reported automatic displays comprise scholastic displays.

10. The method of claim 2 wherein the carriers are trucks.

11. The method of claim 3 wherein the carriers are trucks.

12. The method of claim 4 wherein the carriers are trucks.

13. The method of claim 7 wherein the carriers are trucks.

14. The method of claim 4 wherein the automated displays are shown only upon a request by a user for displays of specifically requested metric displays.

15. The method of claim 4 wherein the automated displays are shown only upon a request by a user for displays of generally requested metric displays.

16. A system for monitoring economic performance within a fleet of carriers comprising:
a communication network that provides information regarding at least individual carriers within the fleet of carriers to a processor;
a processor that contains a software program that:
tabulates at least some of the information to provide a resource of economic performance within the fleet of carriers;
enables graphic representation of at least some measures of the economic performance; and
enables viewing of metrics including at least two parameters for evaluating the economic performance of a specific carrier;
the processor automatically evaluates individual carrier metrics and automatically alerts a designated party of failure to operate within acceptable operating tolerances.

17. The system of claim 16 wherein the metrics include at least one metric selected from the group consisting of order management, dispatch status, invoice status, settlement status and reporting status.

18. The system of claim 16 wherein the at least two parameters for evaluating economic performance are selected from the group consisting of total number of orders, number of electronic orders, order accuracy, revenue/truck, variance in individual carrier performance, settlement status, idle truck count, specific carrier subset performance, invoicing status, reporting status, legal performance status, planned orders, started orders, dispatched orders, available orders, percentage of on-time delivery for specific carrier, load performance of specific carriers for completed trips, number of empty miles/total miles, number of cancelled orders/total orders, number of driving hours/order, number of driving hours/specific carrier per day, week or month, average speed/specific carrier, and number and/or value of legal citations/specific carrier.

19. The system of claim 16 wherein the carriers are trucks.

20. The system of claim 17 wherein the carriers are trucks.
